(19) United States
(12) Patent Application Publication
(10) Pub. No.: US 2015/0221535 A1
(43) Pub. Date: Aug. 6, 2015

(54) TEMPERATURE MEASUREMENT USING SILICON WAFER REFLECTION INTERFERENCE

(71) Applicants: Andrew Nguyen, San Jose, CA (US); Jiping Li, Palo Alto, CA (US); Aaron Hunter, Santa Cruz, CA (US)

(72) Inventors: Andrew Nguyen, San Jose, CA (US); Jiping Li, Palo Alto, CA (US); Aaron Hunter, Santa Cruz, CA (US)

(21) Appl. No.: 14/170,201

(22) Filed: Jan. 31, 2014

(51) Int. Cl. H01L 21/67; G01K 11/12

(52) U.S. Cl. CPC H01L 21/67248; G01K 11/125

(57) ABSTRACT

Temperature measurement of a silicon wafer is described using the interference between reflections off surfaces of the wafer. In one example, the invention includes a silicon processing chamber, a wafer holder within the chamber to hold a silicon substrate for processing, and a laser directed to a surface of the substrate. A photodetector receives light from the laser that is reflected off the surface directly and through the substrate and a processor determines a temperature of the silicon substrate based on the received reflected light.

### FIELD

The present description relate to the field of semiconductor wafer processing and in particular to measuring the temperature of a wafer.

### DISCUSSION OF RELATED ART

Semiconductor and micromechanical devices are often constructed in groups on a silicon wafer. After the wafer is fully processed, the wafer is diced into individual chips. These silicon chips are then packaged in some way for use with an electronic device. During processing, the wafer can be moved into different chambers for exposure to various coating, etching, cleaning, and photolithography processes. For many of the processes, extreme temperature and chemical environments are used. The processing operations are affected by the temperature in the chamber and the temperature of the wafer.

Wafer temperature has significant impact on plasma etching process performance. Variations in wafer temperature can cause significant variations in the etch rate and the size of the etched features from wafer to wafer and tool to tool. If the etch rate is not precisely controlled, then either all features must be made larger to accommodate the variations (larger critical dimension (CD) or many of the wafers will have fabrication errors that ruin a chip. A larger CD and lower chip yields both increase the cost of manufacturing good chips.

### SUMMARY

Temperature measurement of a silicon wafer is described using the interference between reflections off surfaces of the wafer. In one example, the invention includes a silicon processing chamber, a wafer holder within the chamber to hold a silicon substrate for processing, and a laser directed to a surface of the substrate. A photodetector receives light from the laser that is reflected off the surface directly and through the substrate and a processor determines a temperature of the silicon substrate based on the received reflected light.

### BRIEF DESCRIPTION OF THE DRAWINGS

Embodiments of the present invention are illustrated by way of example, and not limitation, in the figures of the accompanying drawings.

FIG. 1 is a diagram of a wafer processing chamber with a wafer temperature measurement system according to an embodiment of the invention.

FIG. 2 is a cross-sectional diagram of a portion of a wafer and wafer chuck with an optical fixture according to an embodiment of the invention.

FIG. 3 is a cross-sectional diagram of a portion of a processing chamber housing with an optical fixture according to an embodiment of the invention.

FIG. 4 is a process flow diagram for determining the temperature of a wafer in a processing chamber according to an embodiment of the invention.

FIG. 5 is a diagram of graph of a simulation of received reflected light interference over temperature according to an embodiment of the invention.

FIG. 6 is a diagram of a graph of a simulation of received reflected light interference from two lasers over temperature according to an embodiment of the invention.

FIG. 7 is a process flow diagram of measuring temperature during wafer processing according to an embodiment of the invention.

### DETAILED DESCRIPTION

The temperature of a wafer in a processing chamber can be changed by changing the parameters of the process chamber. The heat of the plasma, or other gases and the temperature of the reaction gases can be changed. In addition, wafer carriers in the chamber may have heaters, cooling chambers or both that can be used to change the temperature of the wafer. To best control the temperature of the wafer, the temperature of the wafer should first be measured. By measuring the temperature of a wafer while the wafer is within a processing chamber, the measured temperature can be used to regulate the wafer temperature more precisely. A more precise temperature control provides more precise control over the processes in the chamber. By controlling the etch rate in a plasma etch chamber, for example, the CD of features may be made smaller without risk of etching too far into the feature.

In some cases, a one-time use temperature control wafer is processed within a chamber to measure and calibrate a temperature profile before for the chamber before mass production processing begins. The wafer does not measure the actual temperature but allows the rate of a process to be measured with the chamber set in a particular way. The calibration process can be repeated, adjusting the chamber parameters after each trial, until a known and desired etch rate is achieved. In this way each process and each chamber can be measured and adjusted based on a test run. However, the wafer temperature will drift over time as the chamber equipment is used. The temperature will also vary due to variations in other factors, such as incoming wafer types, input chemistry, input facilities and operators.

By measuring the wafer temperature in the etch chamber directly, the wafer temperature can be adjusted for any variations. The temperature may be measured with or without the presence of plasma in-situ. The wafer temperature can be measured for each wafer process.

While a simple thermocouple or other contact thermometer may seem useful to measure the temperature, for some processes the process chamber is at very high temperature and includes extremely corrosive chemicals. As explained herein, by measuring the interference between light reflected from the front surface and light reflected from the back surface of the wafer, the temperature of the wafer can be determined. The interference can be measured by carefully selecting the light wavelength based on the nature of the wafer.

Silicon, a common wafer material has thermo-optic refraction coefficients. The index of refraction of silicon changes as the temperature of the silicon varies. The change in index of refraction changes the travel time of light propagating through the silicon. By comparing the arrival time of light reflected directly off the silicon to the arrival time of light that travels through the silicon and is reflected off the opposite face of the silicon, the index of refraction of the silicon can be measured. In other words, the difference in travel time between light reflected off the front and back sides of the Si wafer can be measured. One way to determine the difference in travel time is to combine the two reflections and analyze the interference. The delay of the light coming off the back side will cause the two reflected beams to be out of phase. They will then interfere with each other when combined after reflection. This interference signal is normally a sinusoidal function of the temperature of the silicon wafer. The same approach can be used to compare two transmitted light beams but only reflection is described here.

The number of interference fringes is an indication of Si wafer temperature. Each interference fringe (from peak to peak or from valley to valley) represents about 4.5° C. temperature change. The temperature can also be extracted by comparing a simulated signal with the experimental or received signal or by comparing the experimental signal with a pre-generated table or calibration curve.

The interference contrast will degrade as the silicon doping concentration is increased. However, there is still a noticeable interference contrast for heavily doped silicon at 200° C.

To provide a clearer temperature signal throughout the entire interference path (interferogram), two laser wavelengths close to each other may be used. The two wavelengths create an interference “beat” when combined. The beat provides a quick and definite determination of the temperature of the silicon based on the interferogram.

A typical silicon wafer is on the order of 750 μm thick. For such a wafer, the one or more lasers are chosen to have a long coherence length with a wavelength greater than 2 mm. A longer wavelength (e.g. 1.5 μm) may work even better because silicon is more transparent at longer wavelengths. The wavelengths are selected based on a balance of laser availability, transparency of the silicon, thickness of the silicon and photon energies. A photon energy much greater than or near the bandgap energy of the silicon will provide a better and more certain signal.

The laser may be driven either in a continuous mode or wave (CW) or the laser may be modulated. When a modulated laser is used, a lock-in amplifier may be used as described herein to retrieve the interference signal level. This enables a low signal to be detected with a high signal to noise ratio for heavily doped silicon wafers.

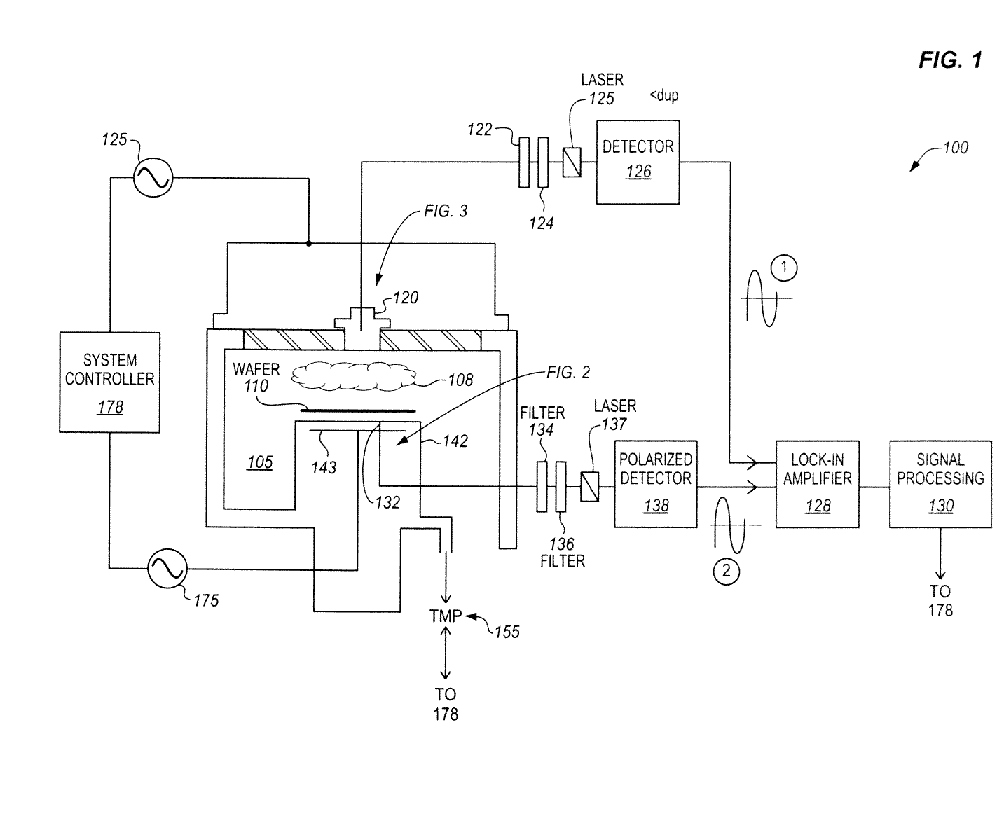

FIG. 1 is a schematic diagram of a plasma etch system 100 including an optical thermal measurement system. The plasma etch system 100 may be any type of high performance etch chamber known in the art, such as, but not limited to, Enabler™, DPS II. AdvantEdge™ G3, E-MAX®, Axiom, Orion, or Mesa CIP chambers, all of which are manufactured by Applied Materials of California, USA. Other commercially available etch chambers may similarly utilize the temperature sensors described herein. While the exemplary embodiments are described in the context of the plasma etch system 100, the thermal measurement described herein is also adaptable to other processing systems used to perform any plasma fabrication process (e.g., plasma deposition systems, etc.) that places a heat load on a wafer.

Referring to FIG. 1, the plasma etch system 100 includes a grounded chamber 105. Process gases are supplied from gas source(s) (not shown) connected to the chamber through a mass flow controller to the interior of the chamber 105. The chamber 105 is evacuated via an exhaust valve connected to a high capacity turbo mechanical pump 155. When plasma power is applied to the chamber 105, a plasma 108 is formed in a processing region over a workpiece 110. A plasma bias power 125 is coupled into a chuck assembly 142 to energize the plasma. The plasma bias power 125 typically has a low frequency between about 2 MHz to 60 MHz, and may be, for example, in the 13.56 MHz band. The plasma etch system 100 may also include additional plasma bias power sources operating at about the 2 MHz band.

A workpiece 110 is loaded through an opening and clamped to a chuck assembly 142 inside the chamber. The workpiece 110, such as a semiconductor wafer, may be any wafer, substrate, or other material employed in the plasma processing art and the present invention is not limited in this respect. The workpiece 110 is disposed on a top surface of a dielectric layer 143 or puck of the chuck assembly. A clamp electrode (not shown) is embedded in the dielectric layer 143. In particular embodiments, the chuck assembly 142 may include heaters and coolant passageways. The heat transfer fluid may be a liquid, such as, but not limited to an ethylene glycol/water mix. A current and flow control system 175 is coupled to control the current supplied to the heaters and coupled to the coolant passageways to control coolant flow through the chuck. In this way the control system can increase or decrease the temperature of the chuck and the wafer.

A system controller 178 is coupled to a variety of different systems, including the RF plasma power 125, the gas control pumps 155 and the temperature controller 175, to control a fabrication process in the chamber. The controller may be connected to the temperature controller 175 to execute temperature control algorithms (e.g., temperature feedback control) and may be either software or hardware or a combination of both software and hardware. The system controller also includes a central processing unit, memory, and input/output interface. The temperature controller 175 is to output control signals affecting the rate of heat transfer between the chuck assembly 142 and a heat source and/or heat sink external to the plasma chamber 105.

To measure the temperature of the wafer an optical system is coupled through the chamber walls above or below the wafer or both. An upper optical fixture 120 directs a laser onto the wafer 110 and receives the reflected light. The reflected light is carried through an optical channel to a narrow band pass filter 122 to filter out stray light. The light then passes through a circular polarizer 124, such as a quarter-wave plate in preparation for passing through a polarizing beam splitter 125. The remaining light is detected in a photodetector 126 and converted to an electrical signal that is connected to a temperature determination system.

Similarly, a lower optical fixture 132 directs laser light onto the bottom of the wafer and channels any reflected light back through a narrow band pass filter 134. a polarizing filter 136, such as a quarter wave plate, and a polarizing beam splitter 137 to a photodetector 138 which converts the light to an electrical signal. In the illustrated example, the two converted light beams are received by a lock-in amplifier which determines the beat frequency between the two beams. The beat frequency is provided to a signal processor 130 to determine the corresponding temperature. This temperature may be provided to the system controller 178 while the wafer is in the chamber and while the wafer is being processed. The system controller may respond to the received temperature by heating or cooling the wafer to change the wafer's temperature. Alternatively, or in addition, the system controller may respond to the wafer's temperature by modifying process parameters to accommodate the measured temperature.

The laser does not introduce any new chemical compounds into the system and so it does not affect the process. In addition, the optical port allows the laser to be projected into the chamber and allows reflected light to be received without any equipment being inserted into the chamber. The temperature may be measured at multiple locations on the wafer and at any and all times before, during, and after wafer processing. The temperature may be measured using a single laser in a single location, multiple lasers or multiple beams from a single laser from either the top or the bottom of the wafer, or from both the top and bottom of the wafer as shown, using one or more lasers directed at one or more locations.

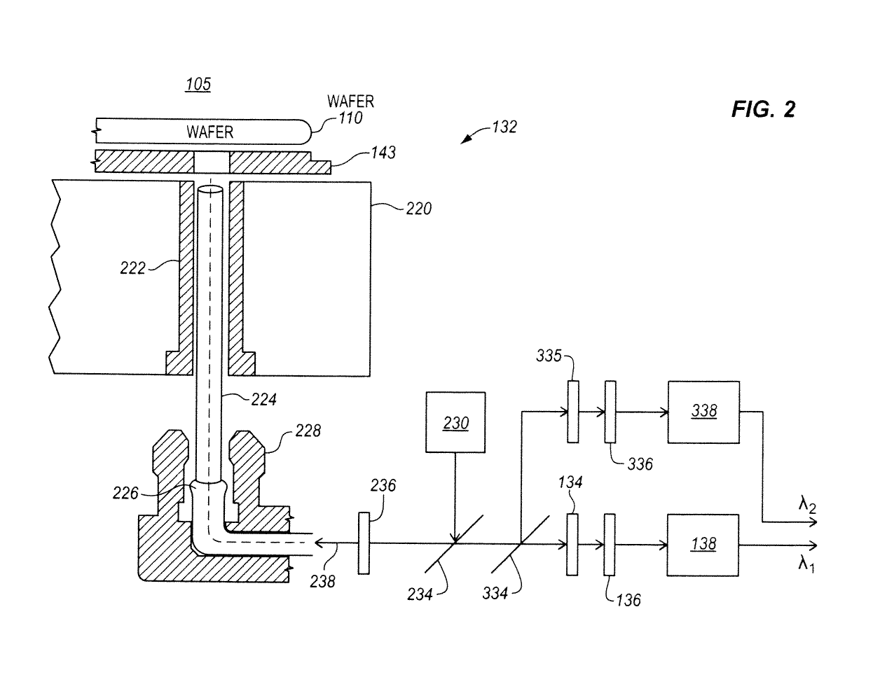

FIG. 2 is a simplified cross-sectional diagram of a portion of wafer chuck 143, for example an electrostatic chuck (ESC). The cooling plate and resistive heater traces are not shown in order to simplify the drawing. The workpiece 110 is clamped to the chuck assembly 143 inside the chamber 105. The chuck assembly is attached to a lift mechanism 220 to control the position and height of the wafer relative to plasma sources, showerheads, and gas sinks and sources inside the chamber. The lift has a protective insert 222 to hold a light pipe 224. The protective insert may be made of any of a variety of different materials that may protect the light pipe or fiber bundle, including black anodized aluminum or PEEK (Poly Ether Ether Ketone). The light pipe may be a glass tube, bundle of tubes or optic fiber bundle to carry light from a laser to the wafer and from the wafer to a photodetector.

The light pipe extends from the chuck lift 220 away from the wafer to a chamber outlet fitting 228. The chamber outlet includes a light pipe connector 226 to channel light to and from the light pipe to and from an external light channel 238. A laser illumination and reflection measurement system is provided outside of the chamber to illuminate the wafer and the receive reflections from the wafer. The particular configuration of this system may be adapted to suit different types of light pipes, wafers, and illumination choices.

In the illustrated example, a laser 230 provides is optically coupled to a polarizing beam splitter 234 which channels light from the laser into the light channel 238. This light travels through the light pipe within the optical fixtures to impinge on the wafer 110. Lenses, collimators, and other optical devices may be provided to focus or diffuse the light on the wafer, depending on the particular implementation. The laser may provide a single narrow wavelength beam or multiple narrow or wide beams depending on the type of temperature measurement being used.

The light reflected from the wafer passes through the light pipe 224 and out of the chamber 105, through a polarizer 236 and the same polarizing beam splitter. The polarized light from the polarizing filter 236 is transmitted through the polarizing beam splitter 234 to the narrow band filter 134 and the second optional polarizing filter 136 to the photodetector 138. In addition to reflected laser light, light that travels from the chamber into the light pipe may include thermal and emission radiation from the wafer, light from electrical and chemical equipment in the chamber, and products of plasma or other reactions. The narrow band filter may be used to filter out all of the other light sources so that the light that impinges on the photodetector is mostly light from the laser. The narrow band filter may be an optical pass band filter that transmits only light with a wavelength about the same as the light emitted by the laser. If the laser emits more than one wavelength, then the narrow band filter may be modified accordingly.

Two or more lasers may be used for either the upper or lower light fixture or both. In FIG. 2 additional components are shown that may be used to provide additional laser illumination and measure additional laser reflections. Two or more lasers of different frequencies may be combined at the source 230 using fibers or other optical combiners and directed toward the wafer. On the reflected optical path, the two wavelengths may be independently measured. An example of how to independently measure the two reflected wavelengths is to use an additional polarizing beam splitter 334 to split out a portion of the light. The split out light may then be passed through a narrow band filter 335 for the second wavelength, filtering out the first wavelength, and a polarizer 336 to then impinge on a second photodetector 338. The electrical signals from the two polarizers 138, 338 represent amplitudes for the reflected light of the first and second wavelengths. This light can be combined to obtain beat frequencies and for other purposes as explained herein.

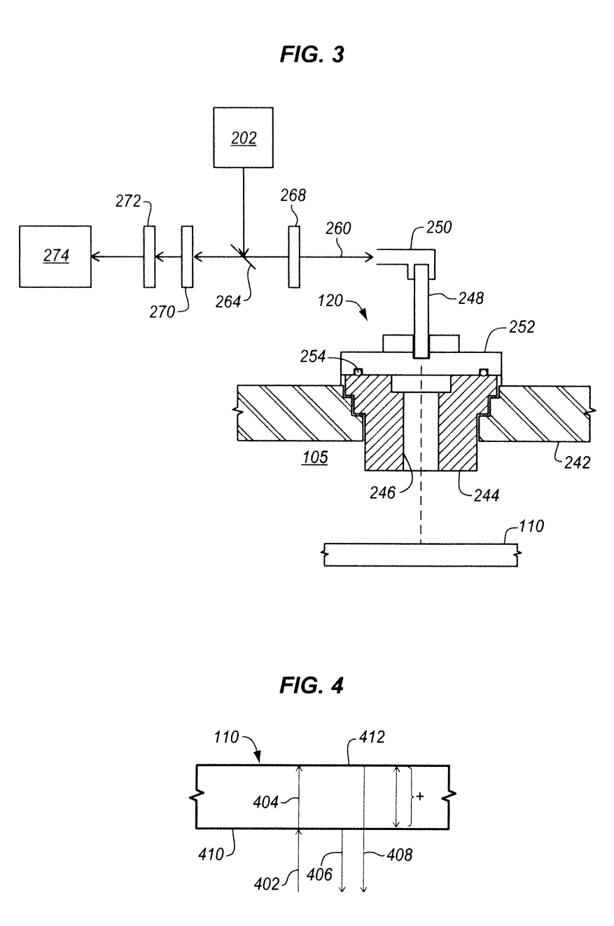

FIG. 3 is a cross-sectional diagram of an optical fixture that may be used in the chamber wall above the wafer. The chamber 105 such as a plasma processing chamber or other type of fabrication chamber has an upper wall or lid 242 of ceramic above the wafer 110. An optical fixture 244 is mounted in this lid 242 and sealed against the lid with an O-ring 254. The optical fixture carries a light pipe 246 of glass or fiber or another construction as described above. The light pipe carries laser light to the wafer and receives reflections of the laser light from the wafer. The light pipe may include various other optical components to direct, steer, or focus the laser light onto the wafer and to collect reflected light.

The light pipe 248 extends away from the chamber 105 and may be connected to any of a variety of connectors, guides, elbows, or junctions 250 to carry the light into an optical channel 260. Similar to the lower channel, a laser 262 generates one or more laser light beams in continuous or pulsed wave form. This laser illumination is directed into the light channel by a polarizing beam splitter 264. Similarly light from the chamber is polarized in a filter 268, transmitted through the polarizing beam splitter 264, pass band filtered 270, polarization filtered 272 and then received at a photodetector 274. As mentioned above, more than one laser wavelength may be used by adding additional lasers and detectors as shown in the example of FIG. 2 or in other ways.

While a glass light pipe with polarization beam optics is shown, light may be directed to and received from the wafer using any other type of optical system. Optical fibers with couplers and combiners may be used. Separate channels may be used for the transmitted and reflected light. Collimating or focusing optics may be used to direct light from one channel and receive a reflection in a separate nearby channel. Other variations may be used depending on the particular implementation.

FIG. 4 is a diagram of the light paths caused by the incident laser light on a wafer. The laser light 402 strikes a top or bottom surface of the silicon wafer 110, deepening on whether the laser light come from above or below the wafer. A portion 406 of the incident laser light 402 is reflected off the near surface 410 of the wafer. Another portion 404 of the laser light is transmitted through the first surface 410 and is reflected from the far surface 412 of the wafer 110. The far surface is the other one of either the bottom or top surface of the wafer. The light 408 reflected from the far surface 412 propagates parallel to the light 406 reflected from the near surface 410. While the light beams are shown as being parallel and spaced apart, they will typically be coincident. As a result, the reflected beams 406, 408 will be combined.

FIG. 4 is a simplified diagram showing only the light beams of interest. Some of the light will be lost. Some of the light will be transmitted through the far side 412 of the wafer. Some the light reflected from the far side 412 will also be reflected from the near side 410 of the wafer and not combine with the other reflected light 406. Some of the light will be absorbed by the wafer as heat. Some of the light will be scattered within the light at oblique angles and reflected or transmitted in different directions. The intensity of the laser may be selected to provide enough reflected light to allow an accurate measurement notwithstanding all of the losses within and through the wafer.

Since the beam 408 reflected from the far surface has traveled farther than the beam 406 reflected off the near surface, the two beams are out of phase. The difference in distance is twice the thickness (t) of the wafer. In addition, since the beam reflected off the far surface has propagated through the wafer which has a different index of refraction than the environment of the chamber 105 (typically ambient air, nitrogen, carbon dioxide, or some other gaseous environment depending on the processing performed in the chamber), this beam has been delayed. The index of refraction (n) is defined as the ratio of the speed of light in a vacuum (c) to the speed of light in the medium (v), n=c/v, (n>1) so the beam reflected off the far side of the wafer travels slower (v) than c by an amount determined by the index of refraction (n) of the wafer, v=c/n.

A polysilicon wafer has an index of refraction greater than 3.5 which varies depending on the amount any doping and depending on the temperature of the wafer so the light beam reflected off the far side of the wafer will be slowed significantly.

Considering the temperature of the wafer, the index of refraction (n_{T}) of the wafer at any particular temperature depends on the temperature of the wafer (T).

n_{T}=n₀+n_{C}T Eq. 1

where n₀ is a constant; and n_{C} is the thermo-optic coefficient for the wafer; and T is the Si wafer temperature in degrees C.

Using the variation in the index of refraction with temperature, the temperature of the wafer can be determined in any of a variety of different ways. One approach is to combine the light beams reflected of the near and far faces of the wafer. Since the beams are out of phase, there will be constructive and destructive interference that will create amplitude variations. Description of interference fringe period in terms of Si wafer temperature

The optical path difference (OD) between the light reflected off the near face and the light reflected off the far face can be quantified as

OD=2tn_{T} Eq. 2

where 2t is the additional distance of twice the wafer thickness. For a certain constructive interference that occurs at temperature T1, the distance is:

OD_{T1}=2t(n₀+n_{T1})=mλ Eq. 3

where λ is an interference fringe period.

For the next constructive interference that occurs at temperature T2, the distance is:

OD_{T}=2t(n₀+n_{T2})=(m+l)λ. Eq. 4

This leads to the interference fringe period (λ) in terms of the temperature of the silicon wafer of (T2−T1) to be:

2tn_{C}(T2−T1)=λ. Eq. 5

Using λ=1.06 μm, t=800 μm, and n_{C}=2e⁻⁴, gives (T2−T1)=3.3° C., or one fringe for every 3.3° C. of wafer temperature change.

The starting temperature of the wafer is known. By monitoring for interference beats or fringes the change in temperature as the wafer is heated in the chamber can be measured. The fringes can be measured simply as peaks or valleys in the measured light amplitude.

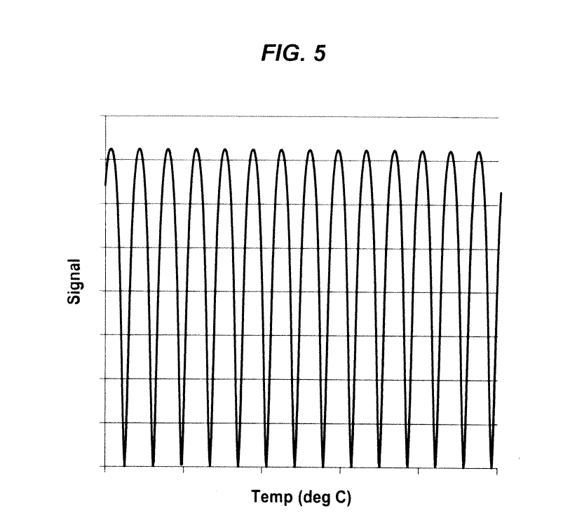

FIG. 5 is a diagram of a simulated photodetector output from the reflection of a single laser. The reflections from the near and far faces of the wafer are combined in the photodetector. A suitable laser for a typical silicon substrate may have a wavelength on the order of 1.3 μm. Constructive interference appears as high amplitude peaks. Destructive interference appears as low amplitude valleys. The nature of the interference changes as the temperature changes. The distance between the peaks changes with the wavelength of the laser, the thermo-optic coefficient (n_{C}) and the thickness of the wafer. The starting signal is a function of the wavelength of the laser, the base refractive index (n₀) and the thickness of the wafer. If the system has first been characterized, then the single laser result at one temperature can be used as a reference or baseline for the single laser result at another temperature. At the start of processing, the temperature of the chamber and the wafer are generally well known, so this temperature can serve as the baseline to chart temperature during the course of the wafer processing.

Multiple lasers may be used for different purposes. The lasers may be directed to different locations on the wafer. Two or more different locations may be used to obtain a measure of the temperature at different locations on the wafer. In plasma processing for example the center of the wafer is often cooler than the periphery of the wafer. The temperature difference can be measured and compensated using lasers directed at multiple locations. Specific locations may also be selected based on the chamber. A particular chamber may have hot spots or cool spots. The effect of these spots on the laser can be measured using multiple locations on the wafer and compensated for if desired. In addition, a second measurement point may be used to compare with the first measurement point to ensure that the first system is working or that the first point is providing reasonable results. A second laser may also serve as a backup in the event that the first laser system fails.

In the single laser example above, the first laser is used as a reference point against itself. Measurements at different times while the chamber is heated correspond to different temperatures. The earlier lower temperature times are used as a reference for the later higher temperature measurements. Since the later measurements are closer to the processing temperatures, the later measurements are more important. Referencing against earlier temperatures provides a better basis for the later temperatures.

Alternatively, a second laser with a different wavelength may be used to provide a reference for the temperature measurements. In this case, the second laser is measuring a portion of the wafer that is expected to be at about the same temperature as the portion of the wafer measured by the first laser. The two lasers may measure the same or very nearby locations. The second laser may be coupled into the same light pipe as the first laser using appropriate combining optics. The second laser may instead be coupled into a different light pipe. Alternatively, the second laser may be directed at the other face of the wafer. As an example there may be one light pipe in an optical fixture below the wafer and another light pipe in an optical fixture above the wafer as shown for example in FIG. 1. The two light pipes are coupled into two different lasers with different wavelengths.

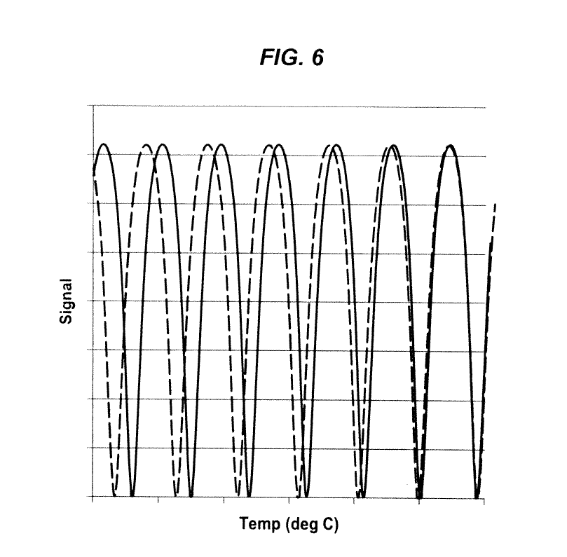

FIG. 6 is a diagram of a simulated photodetector output from the reflection of two lasers with different wavelengths. The two wavelengths are both about 1.3 μm for a typical 200 mm silicon wafer. The wavelengths differ by 2-10%, depending on the particular selected wavelengths and available lasers. The difference between the wavelengths will determine the beat frequency between the interference curves of each laser. More similar wavelengths will have a higher beat frequency and more different wavelengths will have a lower beat frequency. In one example, one laser is at 1.30 μm and the other is at 1.35 μm, however the wavelengths may be adapted to suit different wafer materials and hardware requirements. The reflections from the near and far faces of the wafer are combined for each laser in a photodetector. If the beams are combined in a single light pipe or optic fiber bundle, then a single photodetector may be used. Alternatively, abeam splitter or separate optical paths may be used so that different photodetectors are used for the two wavelengths.

FIG. 6 shows two sinusoidal curves, one for each laser. For each curve, constructive interference appears as high amplitude peaks. Destructive interference appears as low amplitude valleys. As mentioned above, the distance between the peaks changes with the wavelength of the laser. With all other parameters being the same for the two curves, the peaks will line up only at certain temperatures. These temperatures can be determined or estimated mathematically. In the diagram, the two curves align at the rightmost peak. At the next peak to the right (not shown) the peaks will diverge in the opposite direction. After a few more cycles, the peaks will look like the left most peaks in the diagram. The two curves may be combined and the beat frequency between the two curves will provide a third set of peaks and valleys. This can be used to determine the temperature.

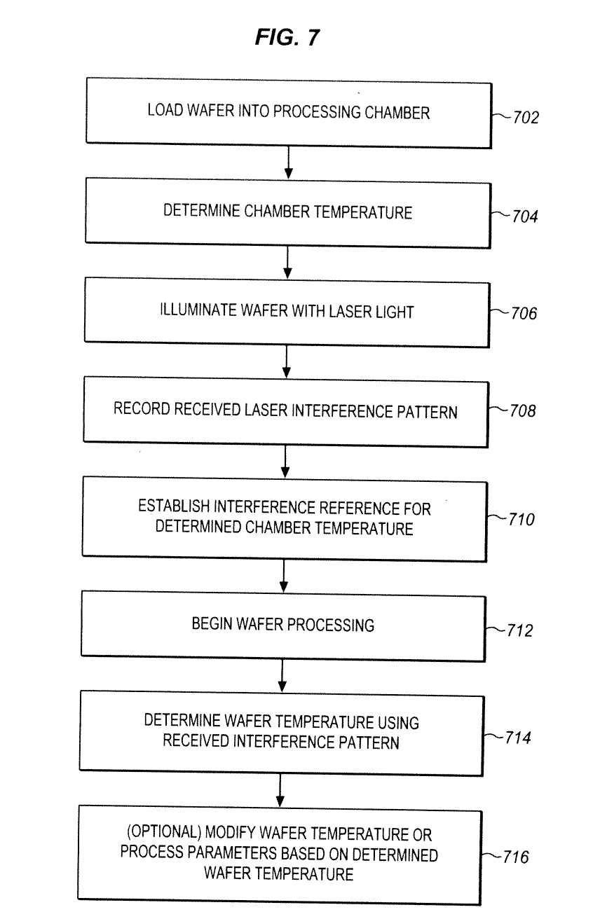

FIG. 7 is a process flow diagram showing an example of measuring the temperature of a wafer according to an embodiment of the invention. At block 702 a wafer is loaded into a wafer processing chamber. The chamber may be configured for any of a variety of different processes and includes one or more optical fixtures for illuminating the wafer and receiving reflections. There may be one or more laser illumination points in nearby, opposing, or distant positions on the surface of the wafer. At 704, the chamber temperature is determined. This may be done in any conventional manner such as by using a thermometer. Typically the chamber is at ambient temperature before processing begins.

At 706, the wafer is illuminated with laser light. This is first done when the chamber is at a known temperature. Laser light is preferred because it provides an inexpensive source of coherent light within a narrow band of wavelengths. However, other light sources may be used depending on the particular implementation. At 708, the laser light reflected off the wafer is received and combined to form an interference pattern. This interference pattern may be recorded. Reflections from more than one laser may be used separately or in combinations. At 710 an interference patter reference is determined for the chamber temperature that was determined earlier.

At 710 the wafer processing begins. The processing is a type of processing that changes the temperature of the wafer. Typically a wafer is heating during processing, however, the invention is not so limited. In plasma processing, a wafer may change from an ambient 20° C. to over 300° C. As the wafer is heated, the interference pattern will change. This change can be recorded and compared to the reference pattern. Based on this comparison at 712 the wafer temperature is determined using the received interference pattern. This temperature may be used in a variety of different ways. As examples, at 714 the temperature may optionally be used as a basis for adjusting the wafer temperature with heaters or coolant or for modifying process parameters. The temperature may also be used as a quality control measure to determine whether the process is being performed within expected limits.

In this description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicate that two or more elements are in either direct or indirect (with other intervening elements between them) physical, optical, or electrical contact with each other, and/or that the two or more elements co-operate or interact with each other (e.g., as in a cause an effect relationship).

In the following description and claims, the terms “chip” and “die” are used interchangeably to refer to any type of microelectronic, micromechanical, analog, or hybrid small device that is suitable for packaging and use in a computing device.

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. An apparatus comprising:
a silicon processing chamber;
a wafer holder within the chamber to hold a silicon substrate for processing;
a laser directed to a surface of the substrate;
a photodetector to receive light from the laser that is reflected off the surface directly and through the substrate; and
a processor to determine a temperature of the silicon substrate based on the received reflected light.

2. The apparatus of claim 1, further comprising a second laser directed to a second surface of the substrate, the second surface being opposite the first surface; and
a second photodetector to receive light from the second laser that is reflected off the second surface directly and through the substrate,
wherein the processor determines the temperature also based on the received reflected light from the second photodetector.

3. The apparatus of claim 1 further comprising, between the silicon substrate and the photodetector, a quarter wave plate to polarize reflected light before a polarizing beam splitter to direct the reflected light to the photodetector through the polarizing beam splitter.

4. The apparatus of claim 1, wherein the processor determines a temperature by comparing a number of interference fringes to a table of corresponding temperature.

5. The apparatus of claim 1, wherein the processor determines a temperature by comparing a simulated signal with the received reflected light.

6. The apparatus of claim 1, wherein the processor determines a temperature by comparing a pre-generated calibration signal with the received reflected light.

7. The apparatus of claim 1, wherein the laser generates a laser light wavelength at which the substrate is transparent.

8. The apparatus of claim 1, wherein the laser generates two different laser light wavelengths that interfere with each other.

9. The apparatus of claim 1, wherein the laser generates modulated light, the apparatus further comprising a lock-in amplifier coupled to the photodetector to lock into the modulation of the reflected light to receive the reflected light.

10. A method comprising:
illuminating a wafer inside a processing chamber with laser light;
receiving a first reflection of the laser from a near surface of the wafer;
receiving a second reflection of the laser through the wafer from a far surface of the laser;
combining the first and the second received reflections;
analyzing an interference pattern of the reflections; and
determining a wafer temperature based on the analysis.

11. The method of claim 10, further comprising;
determining an initial temperature of the wafer before determining a wafer temperature based on the analysis;
analyzing an initial interference pattern of the reflections at the determined initial temperature; and
wherein determining a wafer temperature compress using the initial temperature and the initial interference pattern as a reference.

12. The method of claim 11 further comprising heating the chamber with the wafer inside the chamber to increase the temperature of the wafer after determining an initial temperature and wherein receiving a first and second reflection comprises receiving the first and second reflection as the temperature of the wafer increases.

13. The method of claim 10, further comprising:
illuminating a wafer inside the processing chamber with a second laser light at a second wavelength;
receiving a first reflection of the second laser from a near surface of the wafer;
receiving a second reflection of the second laser through the wafer from a far surface of the laser;
combining the first and the second received reflections of the second laser;
comparing a first interference pattern of the first and second received reflections of the first laser and a second interference pattern of the first and second received reflections of the second laser reflections; and
determining a wafer temperature based on the comparison.

14. The method of claim 13, wherein the illuminating a wafer with a second laser comprising illuminating the wafer on an opposite side of the wafer from the first laser illumination.

15. The method of claim 13, wherein illuminating a wafer with a first laser comprises illuminating the wafer through a light pipe directed to the wafer and wherein illuminating a wafer with a second laser comprises illuminating the wafer through the same light pipe.

16. The method of claim 13, wherein comparing an interference pattern comprises determining an interference fringe pattern between the first interference pattern and the second interference pattern and wherein determining a wafer temperature comprises mapping the fringe pattern to a temperature scale.

17. The method of claim 16, wherein the temperature scale is determined based on the thermo-optic coefficient of the wafer and the thickness of the wafer through which the second reflection of the first laser and the second reflection of the second wafer travels.

18. An apparatus comprising:
a silicon processing chamber;
a wafer holder within the chamber to hold a silicon substrate for processing, the silicon substrate having first and second opposite faces;
a first laser directed to a surface of the substrate;
a first photodetector to receive light from the first laser that is reflected off the first face of the wafer and to receive light that is reflected off the second face of the laser after traversing through the wafer between the first and second faces and to generate a first electrical interference pattern; and
a second laser directed to a surface of the substrate;
a second photodetector to receive light from the second laser that is reflected off the second face of the wafer and to receive light that is reflected off the first face of the laser after traversing through the wafer between the second and first faces and to generate a second electrical interference pattern; and
a processor to receive the first and second electrical interference patterns and to compare the received interference patterns to determine a temperature of the silicon substrate.

19. The apparatus of claim 18, further comprising:
a first light pipe coupled to the chamber directed to the first face of the wafer to transmit the first laser light to the wafer and to receive reflections, and
a second light pipe coupled to the chamber directed to the second face of the wafer to transmit the second laser light to the wafer and to receive reflections.

20. The apparatus of claim 18, wherein the processor determines a temperature by comparing a number of interference fringes to a temperature scale.
